(19) United States
(12) Patent Application Publication
(10) Pub. No.: US 2026/0140452 A1
(43) Pub. Date: May 21, 2026

(54) MACHINE LEARNING BASED METROLOGY UPSAMPLING USING A TRANSFORMER ARCHITECTURE

(71) Applicant: KLA Corporation, Milpitas, CA (US)

(72) Inventors: Sven Boese, Dresden (DE); Philip Groeger, Dresden (DE)

(21) Appl. No.: 18/952,833

(22) Filed: Nov. 19, 2024

(51) Int. Cl. G03F 7/00; G06N 3/0455; G06N 3/0499; G06N 3/08

(52) U.S. Cl. CPC G03F 7/706841; G03F 7/70625; G03F 7/70633; G03F 7/706847; G06N 3/0455; G06N 3/0499; G06N 3/08

(57) ABSTRACT

Methods and systems for upsampling specimen information are provided. In general, the embodiments are configured for upsampling metrology information for a specimen using a transformer architecture. The transformer is configured for self-attention and cross-attention. Inputs to an encoder of the transformer for sparse locations on a specimen may include metrology information and coordinates of the sparse locations in addition to other information such as additional metrology variables and information generated by a process tool that performs a process on the specimen. Inputs to a decoder of the transformer for the dense locations include only the coordinates of the dense locations and some information generated for the dense locations by the process tool. The decoder outputs the metrology information for the dense locations.

### BACKGROUND OF THE INVENTION

### 1. Field of the Invention

The present invention generally relates to methods and systems for upsampling information for a specimen. Certain embodiments relate to methods and systems that include or use a machine learning (ML) based transformer for upsampling metrology information generated for relatively sparse locations on a specimen to relatively dense locations on the specimen.

### 2. Description of the Related Art

The following description and examples are not admitted to be prior art by virtue of their inclusion in this section.

Fabricating semiconductor devices such as logic and memory devices typically includes processing a substrate such as a semiconductor wafer using a large number of semiconductor fabrication processes to form various features and multiple levels of the semiconductor devices. For example, lithography is a semiconductor fabrication process that involves transferring a pattern from a reticle to a resist arranged on a semiconductor wafer. Additional examples of semiconductor fabrication processes include, but are not limited to, chemical-mechanical polishing (CMP), etch, deposition, and ion implantation. Multiple semiconductor devices may be fabricated in an arrangement on a single semiconductor wafer and then separated into individual semiconductor devices.

Metrology processes are used at various steps during a semiconductor manufacturing process to monitor and control the process. Metrology processes are different than inspection processes in that, unlike inspection processes in which defects are detected on a specimen, metrology processes are used to measure one or more characteristics of the specimen that cannot be determined using currently used inspection tools. For example, metrology processes are used to measure one or more characteristics of a specimen such as a dimension (e.g., line width, thickness, etc.) of features formed on the specimen during a process such that the performance of the process can be determined from the one or more characteristics. In addition, if the one or more characteristics of the specimen are unacceptable (e.g., out of a predetermined range for the characteristic(s)), the measurements of the one or more characteristics of the specimen may be used to alter one or more parameters of the process such that additional specimens manufactured by the process have acceptable characteristic(s).

Metrology processes are also different than defect review processes in that, unlike defect review processes in which defects that are detected by inspection are re-visited in defect review, metrology processes may be performed at locations at which no defect has been detected. In other words, unlike defect review, the locations at which a metrology process is performed on a specimen may be independent of the results of an inspection process performed on the specimen. In particular, the locations at which a metrology process is performed may be selected independently of inspection results. In addition, since locations on the specimen at which metrology is performed may be selected independently of inspection results, unlike defect review in which the locations on the specimen at which defect review is to be performed cannot be determined until the inspection results for the specimen are generated and available for use, the locations at which the metrology process is performed may be determined before an inspection process has been performed on the specimen.

One significant challenge in metrology is measuring a suitable number of locations on the specimen within an acceptable amount of time. For example, metrology processes may be used to measure all points on a specimen, but the time involved in such measurements make them impractical for meeting throughput requirements, particularly for inline use. Metrology processes (e.g., for measurement of overlay (OVL) and critical dimension (CD)) therefore usually rely on as few measurement points and specimens/lots as possible to capture systematic signatures that are then modeled for automated process control (APC) purposes to try to maximize throughput. In just one OVL, non-limiting example, 2 wafers per chuck may be measured with 100-1000 points (although any suitable number of measurement points may be used) and modeled using 5-10th order wafer and field polynomials.

Reducing the number of measurement points for the purposes of throughput presents a number of challenges, and a number of approaches have been proposed to overcome one or more of those challenges. For example, some proposed methods try to generate measurements on non-measured specimens (“virtual metrology”) based on related measured specimens and fine alignment of the unmeasured target specimen. If sparse measurements are available on the target specimen, some proposed methods use a rigid architecture, a fully connected artificial neural network that is implemented as computer models with a fixed number of input samples per specimen. Another proposed method creates location-fine parameters based on context and process corrections (e.g., to flag outlier specimens or predict correctables). An additional proposed method upsamples location-fine scatterometry data based on tool spectra (no context is input-only a machine learning (ML) optical (OCD) model).

So far, such proposed methods are not applied in high volume manufacturing (HVM) environments due to ever-changing measurement and process conditions. The proposed methods also generally focus on predicting non-measured specimens, which is a substantially difficult task and different from upsampling metrology results for the same specimen on which metrology was performed.

The currently available method and systems have a number of additional important disadvantages. For example, model-based APC corrections are tightly bound to the spatial sampling of the metrology, and relatively sparse sampling dictates an upper limit with regards to model order (a relatively high-frequency signature cannot be detected or corrected). Another example of a disadvantage is that model selection is not trivial and depends strongly on the detected signature and spatial sampling. An additional disadvantage is that integration of various data sources is not possible with classical model-based process control (i.e., relying on one metrology data source). A further disadvantage is that many ML related methods designed to improve modeling and/or “densify” the data (upsampling) rely on a fixed template with regards to input and output data/dimensionality (e.g., 100 marks at constant positions are upsampled to 1000 marks at constant positions). Therefore, a change in either the data dimensionality or the precise location of the marks requires complete re-training. Gridding the input/output templates of specimen locations (e.g., to allow the application of architectures like convolutional neural networks (CNNs)) brings its own problems. For example, the interpolation step can introduce artefacts that disadvantageously affect the training of the CNN downstream of the interpolation.

Accordingly, it would be advantageous to develop systems and methods for upsampling specimen information that do not have one or more of the disadvantages described above.

### SUMMARY OF THE INVENTION

The following description of various embodiments is not to be construed in any way as limiting the subject matter of the appended claims.

One embodiment relates to a system configured for upsampling specimen information. The system includes a computer system and one or more components executed by the computer system. The one or more components include a transformer configured for upsampling specimen information. The transformer includes an encoder configured for transforming first information for first locations on a specimen by self-attention thereby generating a first encoded representation of the first information. The first information includes information generated for the first locations by one or more tools that perform one or more processes on the specimen. The one or more tools include a metrology tool.

The transformer also includes a decoder configured for transforming second information for second locations on the specimen by self-attention thereby generating a second encoded representation of the second information and transforming the first and second encoded representations by cross-attention into metrology information for the second locations. The second specimen locations are more dense than the first specimen locations. The system may be further configured as described herein.

Another embodiment relates to a computer-implemented method for upsampling specimen information. The method includes transforming first information for first locations on a specimen by self-attention thereby generating a first encoded representation of the first information. The first information includes information generated for the first locations by one or more tools that perform one or more processes on the specimen. The one or more tools include a metrology tool. Transforming the first information is performed by an encoder included in a transformer. The transformer is included in one or more components executed by a computer system.

The method also includes transforming second information for second locations on the specimen by self-attention thereby generating a second encoded representation of the second information. In addition, the method includes transforming the first and second encoded representations by cross-attention into metrology information for the second locations. The second locations are more dense than the first specimen locations. Transforming the second information and transforming the first and second encoded representations are performed by a decoder included in the transformer. Each of the steps of the method may be performed as described further herein. The method may include any other step(s) of any other method(s) described herein. The method may be performed by any of the systems described herein.

Another embodiment relates to a non-transitory computer-readable medium storing program instructions executable on a computer system for performing a computer-implemented method for upsampling specimen information. The computer-implemented method includes the steps of the method described above. The computer-readable medium may be further configured as described herein. The steps of the computer-implemented method may be performed as described further herein. In addition, the computer-implemented method for which the program instructions are executable may include any other step(s) of any other method(s) described herein.

### BRIEF DESCRIPTION OF THE DRAWINGS

Further advantages of the present invention will become apparent to those skilled in the art with the benefit of the following detailed description of the preferred embodiments and upon reference to the accompanying drawings in which:

FIGS. 1 and 2 are schematic diagrams illustrating a side view of an embodiment of a system configured as described herein;

FIGS. 3 and 4 are flow charts illustrating embodiments of transformer training and inference, respectively;

FIG. 5 is a block diagram illustrating an embodiment of self-attention for metrology-based information that may be performed by an encoder configured as described herein;

FIG. 6 is a block diagram illustrating an embodiment of a transformer, inputs to the encoder and decoder, and output of the decoder; and

FIG. 7 is a block diagram illustrating one embodiment of a non-transitory computer-readable medium storing program instructions for causing a computer system to perform a computer-implemented method described herein.

While the invention is susceptible to various modifications and alternative forms, specific embodiments thereof are shown by way of example in the drawings and are herein described in detail. The drawings may not be to scale. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DETAILED DESCRIPTION OF THE PREFERRED EMBODIMENTS

Turning now to the drawings, it is noted that the figures are not drawn to scale. In particular, the scale of some of the elements of the figures is greatly exaggerated to emphasize characteristics of the elements. It is also noted that the figures are not drawn to the same scale. Elements shown in more than one figure that may be similarly configured have been indicated using the same reference numerals. Unless otherwise noted herein, any of the elements described and shown may include any suitable commercially available elements.

In general, the embodiments described herein are configured for upsampling specimen information. More specifically, the embodiments described herein are configured for machine learning (ML) based metrology upsampling using a transformer architecture.

In some embodiments, the specimen is a wafer. The wafer may include any wafer known in the semiconductor arts. Although some embodiments may be described herein with respect to a wafer or wafers, the embodiments are not limited in the specimens for which they can be used. For example, the embodiments described herein may be used for specimens such as reticles, flat panels, personal computer (PC) boards, and other semiconductor specimens.

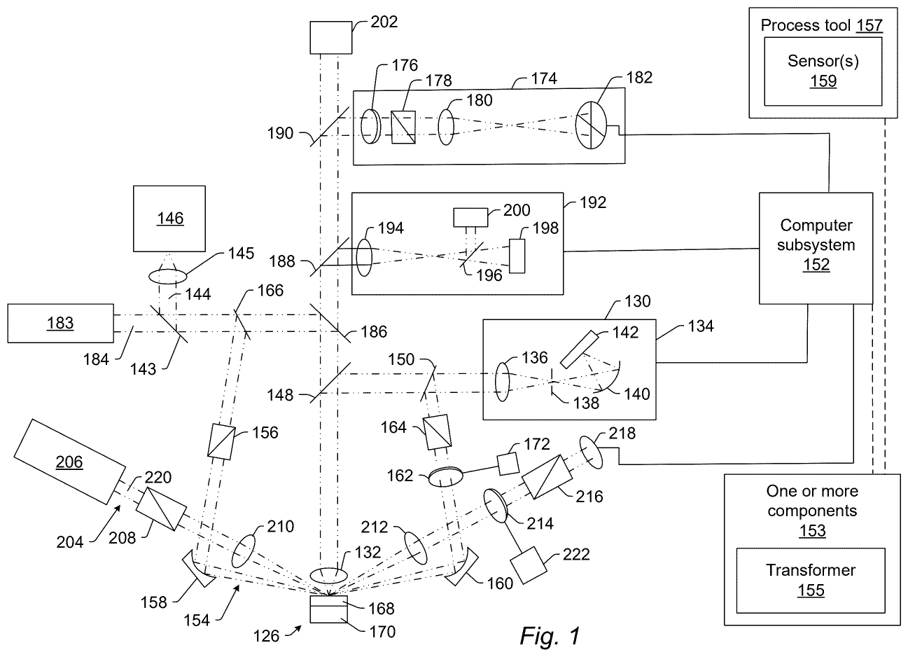

One embodiment of a system configured for upsampling specimen information is shown in FIG. 1. In one embodiment, the system includes a metrology tool configured for generating at least a portion of the first information described further herein by measuring first locations on specimen 126 with one or more of light (as shown in FIG. 1) and electrons (as shown in FIG. 2). The metrology tool includes and/or is coupled to computer subsystem 152.

In general, the metrology tools described herein include at least an energy source, a detector, and a scanning subsystem. The energy source is configured to generate energy that is directed to a specimen by the metrology tool. The detector is configured to detect energy from the specimen and to generate output responsive to the detected energy. The scanning subsystem is configured to change a position on the specimen to which the energy is directed and from which the energy is detected.

In one embodiment, the metrology tool is configured as a light-based metrology tool. FIG. 1 illustrates an embodiment of a system that includes various light-based metrology tools. The metrology tools shown in FIG. 1 are described in more detail in U.S. Pat. No. 6,515,746 to Opsal et al., which is incorporated by reference as if fully set forth herein. Some of the non-essential details of the system presented in this patent have been omitted from the description corresponding to FIG. 1 presented herein. However, it is to be understood that the system illustrated in FIG. 1 may be further configured as described in this patent. In addition, it will be obvious upon reading the description of several embodiments provided herein that the system illustrated in FIG. 1 has been altered to improve upon the system described in U.S. Pat. No. 6,515,746 to Opsal et al. The alterations include upsampling of metrology measurements performed by the metrology tool.

One of the metrology tools is configured as a broadband reflective spectrometer. Broadband reflective spectrometer (BRS) 130 simultaneously probes specimen 126 with multiple wavelengths of light. BRS 130 uses lens 132 and includes a broadband spectrometer 134 which can be of any type commonly known and used in the art. Lens 132 may be a transmissive optical component formed of a material such as calcium fluoride (CaF₂). Such a lens may be a spherical, microscope objective lens with a high numerical aperture (on the order of 0.90 NA) to create a large spread of angles of incidence with respect to the specimen surface, and to create a spot size of about one micron in diameter. Alternatively, lens 132 may be a reflective optical component. Such a lens may have a lower numerical aperture (on the order of 0.4 NA) and may be capable of focusing light to a spot size of about 10-15 microns. Spectrometer 134 shown in FIG. 1 includes lens 136, aperture 138, dispersive element 140, and detector array 142. Lens 136 may be formed of CaF₂.

During operation, probe beam 144 from light source 146 is collimated by lens 145, directed by mirror 143 through mirror 166 to mirror 186, which directs the light through mirror 148 to lens 132, which is then focused onto specimen 126 by lens 132. The light source may include any of the light sources described above. Lens 145 may be formed of CaF₂.

Light reflected from the surface of the specimen passes through lens 132 and is directed by mirror 148 (through mirror 150) to spectrometer 134. Lens 136 focuses the probe beam through aperture 138, which defines a spot in the field of view on the specimen surface to analyze. Dispersive element 140, such as a diffraction grating, prism, or holographic plate, angularly disperses the beam as a function of wavelength to individual detector elements contained in detector array 142.

The different detector elements measure the optical intensities of different wavelengths of light contained in the probe beam, preferably simultaneously. Alternately, detector 142 can be a charge-coupled device (“CCD”) camera or a photomultiplier with suitably dispersive or otherwise wavelength selective optics. It should be noted that a monochrometer could be used to measure the different wavelengths serially (one wavelength at a time) using a single detector element. Further, dispersive element 140 can also be configured to disperse the light as a function of wavelength in one direction, and as a function of the angle of incidence with respect to the specimen surface in an orthogonal direction, so that simultaneous measurements as a function of both wavelength and angle of incidence are possible. Computer subsystem 152 processes the intensity information measured by detector array 142.

Broadband spectroscopic ellipsometer (BSE) 154 is also configured to perform measurements of the specimen using light. BSE 154 includes polarizer 156, focusing mirror 158, collimating mirror 160, rotating compensator 162, and analyzer 164. In some embodiments, BSE 154 may be configured to perform measurements of the specimen using light provided by light source 146, light source 183, or another light source (not shown).

In operation, mirror 166 directs at least part of probe beam 144 to polarizer 156, which creates a known polarization state for the probe beam, preferably a linear polarization. Mirror 158 focuses the beam onto the specimen surface at an oblique angle, ideally on the order of 70 degrees to the normal of the specimen surface. Based upon well known ellipsometric principles, the reflected beam will generally have a mixed linear and circular polarization state after interacting with the specimen, based upon the composition and thickness of the specimen's film 168 and substrate 170.

The reflected beam is collimated by mirror 160, which directs the beam to rotating compensator 162. Compensator 162 introduces a relative phase delay δ (phase retardation) between a pair of mutually orthogonal polarized optical beam components. Compensator 162 is rotated at an angular velocity c about an axis substantially parallel to the propagation direction of the beam, preferably by electric motor 172. Analyzer 164, preferably another linear polarizer, mixes the polarization states incident on it. By measuring the light transmitted by analyzer 164, the polarization state of the reflected probe beam can be determined.

Mirror 150 directs the beam to spectrometer 134, which simultaneously measures the intensities of the different wavelengths of light in the reflected probe beam that pass through the compensator/analyzer combination. Computer subsystem 152 receives the output of detector 142, and processes the intensity information measured by detector 142 as a function of wavelength and as a function of the azimuth (rotational) angle of compensator 162 about its axis of rotation, to solve the ellipsometric values ψ and Δ as described in U.S. Pat. No. 5,877,859 to Aspnes et al., which is incorporated by reference as if fully set forth herein.

A system that includes the broadband reflective spectrometer and broadband spectroscopic ellipsometer described above may also include additional metrology tool(s) configured to perform additional measurements of the specimen using light. For example, the system may include metrology tools configured as a beam profile ellipsometer, a beam profile reflectometer, another optical subsystem, or a combination thereof.

Beam profile ellipsometry (BPE) is discussed in U.S. Pat. No. 5,181,080 to Fanton et al., which is incorporated by reference as if fully set forth herein. BPE 174 includes laser 183 that generates probe beam 184. Laser 183 may be a solid state laser diode from Toshiba Corp. which emits a linearly polarized 3 mW beam at 673 nm. BPE 174 also includes quarter wave plate 176, polarizer 178, lens 180, and quad detector 182. In operation, linearly polarized probe beam 184 is focused on specimen 126 by lens 132. Light reflected from the specimen surface passes up through lens 132 and mirrors 148, 186, and 188, and is directed into BPE 174 by mirror 190.

The position of the rays within the reflected probe beam correspond to specific angles of incidence with respect to the specimen's surface. Quarter-wave plate 176 retards the phase of one of the polarization states of the beam by 90 degrees. Linear polarizer 178 causes the two polarization states of the beam to interfere with each other. For maximum signal, the axis of polarizer 178 should be oriented at an angle of 45 degrees with respect to the fast and slow axis of quarter-wave plate 176. Detector 182 is a quad-cell detector with four radially disposed quadrants that each intercept one quarter of the probe beam and generate a separate output signal proportional to the power of the portion of the probe beam striking that quadrant.

The output signals from each quadrant are sent to computer subsystem 152. By monitoring the change in the polarization state of the beam, ellipsometric information, such as ψ and Δ, can be determined. To determine this information, computer subsystem 152 takes the difference between the sums of the output signals of diametrically opposed quadrants, a value which varies linearly with film thickness for very thin films.

Beam profile reflectometry (BPR) is discussed in U.S. Pat. No. 4,999,014 to Gold et al., which is incorporated by reference as if fully set forth herein. BPR 192 includes laser 183, lens 194, beam splitter 196, and two linear detector arrays 198 and 200 to measure the reflectance of the sample. In operation, linearly polarized probe beam 184 is focused onto specimen 126 by lens 132, with various rays within the beam striking the specimen surface at a range of angles of incidence. Light reflected from the specimen surface passes up through lens 132 and mirrors 148 and 186, and is directed into BPR 192 by mirror 188. The position of the rays within the reflected probe beam correspond to specific angles of incidence with respect to the specimen's surface. Lens 194 spatially spreads the beam two-dimensionally. Beam splitter 196 separates the S and P components of the beam, and detector arrays 198 and 200 are oriented orthogonal to each other to isolate information about S and P polarized light. The higher angle of incidence rays will fall closer to the opposed ends of the arrays. The output from each element in the diode arrays will correspond to different angles of incidence. Detectors arrays 198 and 200 measure the intensity across the reflected probe beam as a function of the angle of incidence with respect to the specimen surface. Computer subsystem 152 receives the output of detector arrays 198 and 200, and derives the thickness and refractive index of thin film layer 168 based on these angular dependent intensity measurements by utilizing various types of modeling algorithms. Optimization routines which use iterative processes such as least square fitting routines are typically employed.

The system shown in FIG. 1 may also include additional components such as detector/camera 202. Detector/camera 202 is positioned above mirror 190, and can be used to view reflected beams off of specimen 126 for alignment and focus purposes.

In order to calibrate BPE 174, BPR 192, BRS 130, and BSE 154, the system may include wavelength stable calibration reference ellipsometer 204 used in conjunction with a reference sample (not shown). For calibration purposes, the reference sample ideally consists of a thin oxide layer having a thickness, d, formed on a silicon substrate. However, in general the sample can be any appropriate substrate of known composition, including a bare silicon wafer, and silicon wafer substrates having one or more thin films thereon. The thickness d of the layer need not be known or be consistent between periodic calibrations.

Ellipsometer 204 includes light source 206, polarizer 208, lenses 210 and 212, rotating compensator 214, analyzer 216, and detector 218. Compensator 214 is rotated at an angular velocity ψ about an axis substantially parallel to the propagation direction of beam 220, preferably by electric motor 222. It should be noted that the compensator can be located either between the specimen and the analyzer (as shown in FIG. 1) or between the specimen and polarizer 208. It should also be noted that polarizer 208, lenses 210 and 212, compensator 214, and polarizer 216 are all optimized in their construction for the specific wavelength of light produced by light source 206, which maximizes the accuracy of the ellipsometer.

Light source 206 produces a quasi-monochromatic probe beam 220 having a known stable wavelength and stable intensity. This can be done passively, where light source 206 generates a very stable output wavelength which does not vary over time (i.e., varies less than 1%). Examples of passively stable light sources are a helium-neon laser, or other gas discharge laser systems. Alternately, a non-passive system can be used where the light source includes a light generator (not shown) that produces light having a wavelength that is not precisely known or stable over time, and a monochrometer (not shown) that precisely measures the wavelength of light produced by the light generator. Examples of such light generators include laser diodes, or polychromatic light sources used in conjunction with a color filter such as a grating. In either case, the wavelength of beam 220, which is a known constant or measured by a monochrometer, is provided to computer subsystem 152 so that ellipsometer 204 can accurately calibrate the optical measurement devices in the system.

Operation of ellipsometer 204 during calibration is further described in U.S. Pat. No. 6,515,746. Briefly, beam 220 enters detector 218, which measures the intensity of the beam passing through the compensator/analyzer combination. Computer subsystem 152 processes the intensity information measured by detector 218 to determine the polarization state of the light after interacting with the analyzer, and therefore the ellipsometric parameters of the specimen. This information processing includes measuring beam intensity as a function of the azimuth (rotational) angle of the compensator about its axis of rotation. This measurement of intensity as a function of compensator rotational angle is effectively a measurement of the intensity of beam 220 as a function of time, since the compensator angular velocity is usually known and a constant.

By knowing the composition of the reference sample, and by knowing the exact wavelength of light generated by light source 206, the optical properties of the reference sample such as film thickness d, refractive index and extinction coefficients, etc., can be determined by ellipsometer 204. Once the thickness d of the film has been determined by ellipsometer 204, then the same sample is probed by the other optical measurement devices BPE 174, BPR 192, BRS 130, and BSE 154 which measure various optical parameters of the sample. Computer subsystem 152 then calibrates the processing variables used to analyze the results from these optical measurement devices so that they produce accurate results. In the above described calibration techniques, all system variables affecting phase and intensity are determined and compensated for using the phase offset and reflectance normalizing factor discussed in U.S. Pat. No. 6,515,746, thus rendering the optical measurements made by these calibrated optical measurement devices absolute.

The above described calibration techniques are based largely upon calibration using the derived thickness d of the thin film. However, calibration using ellipsometer 204 can be based upon any of the optical properties of the reference sample that are measurable or determinable by ellipsometer 204 and/or are otherwise known, whether the sample has a single film thereon, has multiple films thereon, or even has no film thereon (bare sample).

In some embodiments, the metrology tools may have at least one common optical component. For example, lens 132 is common to BPE 174, BPR 192, BRS 130, and BSE 154. In a similar manner, mirrors 143, 166, 186, and 148 are common to BPE 174, BPR 192, BRS 130, and BSE 154. Ellipsometer 204, as shown in FIG. 1, does not have any optical components that are common to the other metrology tools. Such separation from the other metrology tools may be appropriate since the ellipsometer is used to calibrate the other metrology tools.

Computer subsystem 152 may be coupled to the detectors of the metrology tool in any suitable manner (e.g., via one or more transmission media, which may include “wired” and/or “wireless” transmission media) such that the computer subsystem can receive the output generated by the detectors. Computer subsystem 152 may be configured to perform a number of functions with or without the output of the detectors including the steps and functions described further herein. As such, the steps described herein may be performed “on-tool,” by a computer subsystem that is coupled to or part of a metrology tool. In addition, or alternatively, other computer system(s) (not shown) may perform one or more of the steps described herein. Therefore, one or more of the steps described herein may be performed “off-tool,” by a computer system that is not directly coupled to a metrology tool. Computer subsystem 152 may be further configured as described herein.

Computer subsystem 152 (as well as other computer subsystems described herein) may also be referred to herein as computer system(s). Each of the computer subsystem(s) or system(s) described herein may take various forms, including a personal computer system, image computer, mainframe computer system, workstation, network appliance, Internet appliance, or other device. In general, the term “computer system” may be broadly defined to encompass any device having one or more processors, which executes instructions from a memory medium. The computer subsystem(s) or system(s) may also include any suitable processor known in the art such as a parallel processor. In addition, the computer subsystem(s) or system(s) may include a computer platform with high speed processing and software, either as a standalone or a networked tool.

If the system includes more than one computer subsystem, then the different computer subsystems may be coupled to each other such that images, data, information, instructions, etc. can be sent between the computer subsystems. For example, computer subsystem 152 may be coupled to other computer system(s) (not shown) by any suitable transmission media, which may include any suitable wired and/or wireless transmission media known in the art. Two or more of such computer subsystems may also be effectively coupled by a shared computer-readable storage medium (not shown).

The metrology tool may be configured to have multiple modes. In general, a “mode” is defined by the values of parameters of the metrology tool used to generate output for the specimen. Therefore, modes that are different may be different in the values for at least one of the optical parameters of the metrology tool (other than position on the specimen at which the output is generated). For example, for a light-based metrology tool, different modes may use different wavelengths of light. The modes may be different in the wavelengths of light directed to the specimen as described further herein (e.g., by using different light sources, different spectral filters, etc. for different modes).

The multiple modes may also be different in illumination and/or collection/detection. Furthermore, the modes may be different from each other in more than one way described herein (e.g., different modes may have one or more different illumination parameters and one or more different detection parameters). The metrology tool may be configured to generate output for the specimen with the different modes in the same scan or different scans, e.g., depending on the capability of using multiple modes to generate output for the specimen at the same time.

In the field of semiconductor metrology, a metrology tool may include an illumination subsystem which illuminates a target/location, a collection subsystem which captures relevant information provided by the illumination subsystem's interaction (or lack thereof) with a target, device or feature, and a computer subsystem which analyzes the information collected using one or more algorithms. Metrology tools can be used to measure structural and material characteristics (e.g., material composition, dimensional characteristics of structures and films such as film thickness and/or critical dimensions (CDs) of structures, overlay, etc.) associated with various semiconductor fabrication processes. These measurements are used to facilitate process control and/or yield efficiencies in the manufacture of semiconductor dies.

The metrology tool can include one or more hardware configurations which may be used in conjunction with certain embodiments described herein to, e.g., measure the various aforementioned semiconductor structural and material characteristics. Examples of such hardware configurations include, but are not limited to, the following.
1. Spectroscopic ellipsometer (SE)
2. SE with multiple angles of illumination
3. SE measuring Mueller matrix elements (e.g. using rotating compensator(s))
4. Single-wavelength ellipsometers
5. Beam profile ellipsometer (angle-resolved ellipsometer)
6. Beam profile reflectometer (angle-resolved reflectometer)
7. Broadband reflective spectrometer (spectroscopic reflectometer)
8. Single-wavelength reflectometer
9. Angle-resolved reflectometer
10. Imaging system
11. Scatterometer (e.g. speckle analyzer)

The hardware configurations can be separated into discrete operational systems. On the other hand, one or more hardware configurations can be combined into a single tool. One example of such a combination of multiple hardware configurations into a single tool is shown in FIG. 1, which may be further configured as described in U.S. Pat. No. 7,933,026 to Opsal et al., which is incorporated by reference as if fully set forth herein. The systems described herein may be further configured as described in this reference.

FIG. 1 shows, for example, a schematic of an exemplary metrology tool that comprises: a) a broadband SE (i.e., 154); b) a SE (i.e., 204) with rotating compensator (i.e., 214); c) a beam profile ellipsometer (i.e., 174); d) a beam profile reflectometer (i.e., 192); e) a broadband reflective spectrometer (i.e., 130); and f) a deep ultraviolet reflective spectrometer (i.e., 130). In addition, there are typically numerous optical elements in such systems, including certain lenses, collimators, mirrors, quarter-wave plates, polarizers, detectors, cameras, apertures, and/or light sources. The wavelengths for optical systems can vary from about 120 nm to 3 microns. For non-ellipsometer systems, signals collected can be polarization-resolved or unpolarized. FIG. 1 provides an illustration of multiple metrology heads integrated on the same tool. However, in many cases, multiple metrology tools are used for measurements on a single or multiple metrology targets, which is described, e.g. in U.S. Pat. No. 7,478,019 to Zangooie et al., which is incorporated by reference as if fully set forth herein. The embodiments described herein may be further configured as described in this reference.

The illumination subsystem of the certain hardware configurations includes one or more light sources. The light source(s) may generate light having only one wavelength (i.e., monochromatic light), light having a number of discrete wavelengths (i.e., polychromatic light), light having multiple wavelengths (i.e., broadband light) and/or light that sweeps through wavelengths, either continuously or hopping between wavelengths (i.e., tunable sources or swept sources). Examples of suitable light sources include, but are not limited to, a white light source, an ultraviolet (UV) laser, an arc lamp or an electrode-less lamp, a laser sustained plasma (LSP) source such as those commercially available from Energetiq Technology, Inc., Woburn, Massachusetts, a supercontinuum source (such as a broadband laser source) such as those commercially available from NKT Photonics Inc., Morganville, New Jersey, or shorter-wavelength sources such as x-ray sources, extreme UV sources, or some combination thereof. The light source may also be configured to provide light having sufficient brightness, which in some cases may be a brightness greater than about 1 W/(nm cm² Sr). The metrology system may also include a fast feedback to the light source for stabilizing its power and wavelength. Output of the light source can be delivered via free-space propagation, or in some cases delivered via optical fiber or light guide of any type.

The metrology tool may be designed to make many different types of measurements related to semiconductor manufacturing. Certain embodiments described herein may be applicable to such measurements. For example, in certain embodiments, the tool may measure characteristics of one or more targets (more generally and interchangeably referred to herein as “one or more structures”), such as critical dimensions, overlay, sidewall angles (SWAs), film thicknesses, process-related parameters (e.g., focus and/or dose). The targets can include certain regions of interest that are designed to be periodic in nature such as, for example, gratings in a memory die. Targets can include multiple layers (or films) whose thicknesses can be measured by the metrology tool. Targets can include target designs placed (or already existing) on the specimen for use, e.g., with alignment and/or overlay registration operations. Certain targets can be located at various places on the specimen. For example, targets can be located within the scribe lines (e.g., between dies) and/or located in the die itself. In certain embodiments, multiple targets are measured (at the same time or at differing times) by the same or multiple metrology tools as described in U.S. Pat. No. 7,478,019 to Zangooie et al. The data from such measurements may be combined. Data from the metrology tool is used in the semiconductor manufacturing process for example to feed-forward, feed-backward and/or feed-sideways corrections to the process (e.g. lithography, etch) and therefore, might yield a complete process control solution.

As described above, the metrology tool may be configured for generating output for the specimen with one or more wavelengths of light. In addition, the metrology tool may be configured for generating output for the specimen with other electromagnetic radiation such as x-rays. In such instances, some obvious modifications to the system described above may be made but such modifications are within the ordinary skill in the art. In addition, the metrology tool described above may be further configured as described in U.S. Pat. No. 7,929,667 to Zhuang et al., U.S. Pat. No. 9,885,962 to Veldman et al., U.S. Pat. No. 10,013,518 to Bakeman et al., U.S. Pat. No. 10,324,050 to Hench et al., and U.S. Pat. NOo. 10,352,695 to Gellineau et al. and U.S. Patent Application Publication Nos. 2018/0106735 to Dziura et al. and 2019/0017946 to Wack et al., all of which are incorporated by reference as if fully set forth herein. The embodiments described herein may be further configured as described in these publications.

The metrology tool may also or alternatively be configured as an electron beam or other charged particle metrology tool. In an electron beam metrology tool, the energy directed to the specimen includes electrons, and the energy detected from the specimen includes electrons. In one such embodiment shown in FIG. 2, the metrology tool includes electron column 122, and the system includes computer system 124 coupled to the metrology tool. Computer system 124 may be configured as described above. In addition, such a metrology tool may be coupled to another one or more computer systems in the same manner described above and shown in FIG. 1.

As also shown in FIG. 2, the electron column includes electron beam source 126 configured to generate electrons that are focused to specimen 128 by one or more elements 130. The electron beam source may include, for example, a cathode source or emitter tip, and one or more elements 130 may include, for example, a gun lens, an anode, a beam limiting aperture, a gate valve, a beam current selection aperture, an objective lens, and a scanning subsystem, all of which may include any such suitable elements known in the art.

Electrons returned from the specimen (e.g., secondary electrons) may be focused by one or more elements 132 to detector 134. One or more elements 132 may include, for example, a scanning subsystem, which may be the same scanning subsystem included in element(s) 130.

The electron column may include any other suitable elements known in the art. In addition, the electron column may be further configured as described in U.S. Pat. No. 8,664,594 issued Apr. 4, 2014 to Jiang et al., 8,692,204 issued Apr. 8, 2014 to Kojima et al., U.S. Pat. No. 8,698,093 issued Apr. 15, 2014 to Gubbens et al., and U.S. Pat. No. 8,716,662 issued May 6, 2014 to MacDonald et al., which are incorporated by reference as if fully set forth herein.

Although the electron column is shown in FIG. 2 as being configured such that the electrons are directed to the specimen at an oblique angle of incidence and are scattered from the specimen at another oblique angle, the electron beam may be directed to and scattered from the specimen at any suitable angles. In addition, the electron beam metrology tool may be configured to use multiple modes to generate output for the specimen as described further herein (e.g., with different illumination angles, collection angles, etc.). The multiple modes of the electron beam metrology tool may be different in any electron beam related parameters of the metrology tool.

Computer system 124 may be coupled to detector 134 as described above. The detector may detect electrons returned from the surface of the specimen thereby forming electron beam images of (or other output for) the specimen. The electron beam images may include any suitable electron beam images. Computer system 124 may be configured to perform any step(s) described herein. A system that includes the metrology tool shown in FIG. 2 may be further configured as described herein.

FIGS. 1 and 2 are provided herein to generally illustrate configurations of a metrology tool that may be included in the system embodiments described herein. Obviously, the metrology tool configurations described herein may be altered to optimize the performance of the metrology tool as is normally performed when designing a commercial metrology tool. In addition, the systems described herein may be implemented using an existing metrology tool (e.g., by adding functionality described herein to an existing metrology tool) such as the tools that are commercially available from KLA Corp., Milpitas, Calif. For some such systems, the methods described herein may be provided as optional functionality of the metrology tool (e.g., in addition to other functionality of the metrology tool). Alternatively, the metrology tool described herein may be designed “from scratch” to provide a completely new system.

Although the metrology tool is described above as being a light or electron beam metrology tool, the metrology tool may be an ion beam metrology tool. Such a metrology tool may be configured as shown in FIG. 2 except that the electron beam source may be replaced with any suitable ion beam source known in the art. In addition, the metrology tool may include any other suitable ion beam system such as those included in commercially available focused ion beam (FIB) systems, helium ion microscopy (HIM) systems, and secondary ion mass spectroscopy (SIMS) systems.

As noted above, the metrology tool is configured for directing energy (e.g., light, electrons, etc.) to and detecting energy from a physical version of the specimen thereby generating output for the physical version of the specimen. In this manner, the metrology tool may be configured as an “actual” tool, rather than a “virtual” tool. However, a storage medium (not shown) and computer subsystem 152 shown in FIG. 1 may be configured as a “virtual” system. In particular, the storage medium and the computer subsystem may be configured as a “virtual” metrology tool as described in commonly assigned U.S. Pat. No. 8,126,255 issued on Feb. 28, 2012 to Bhaskar et al. and U.S. Pat. No. 9,222,895 issued on Dec. 29, 2015 to Duffy et al., which are incorporated by reference as if fully set forth herein. The embodiments described herein may be further configured as described in these patents.

The system includes a computer system, which may include any configuration of any of the computer subsystem(s) or system(s) described above, and one or more components executed by the computer system. For example, as shown in FIG. 1, the system may include computer subsystem 152 and one or more components 153 executed by the computer subsystem. The one or more components include transformer 155 configured for upsampling specimen information. The transformer is configured for upsampling specimen information like metrology via machine learning (ML). In other words, the transformer upsamples the specimen information not using a physical or other forward model, but learns to upsample specimen information via a ML architecture and training. In particular, a “transformer” as that term is used herein has an artificial neural network architecture that is implemented as a computer model. Some particularly advantageous configurations for the architecture are described further herein.

The transformer described herein, therefore, does not perform forward simulation or rule-based approaches and, as such, a model of the physics of the processes involved in generating an actual metrology measurement for a specimen (for which an upsampled metrology measurement is being generated) is not necessary. Instead, as described further herein, the transformer can be learned (in that its parameters can be learned) based on a suitable training set of data. As described further herein, such transformers have a number of advantages for the embodiments described herein. In addition, the transformer will have a deep learning (DL) architecture in that the transformer will include multiple layers, which perform a number of algorithms or transformations. The number of layers included in the transformer may be use case dependent. The layers included in the transformer may be configured as described further herein.

The transformer includes an encoder configured for transforming first information for first locations on a specimen by self-attention thereby generating a first encoded representation of the first information. The terms “first” and “second” as used herein are not meant to indicate any preferential, spatial, temporal or other characteristics, but are merely meant to indicate different things, like different locations, different information, etc. In addition, although the embodiments are described herein with respect to “locations on a specimen” (used interchangeably herein with the term “specimen locations”), the locations may be any locations on the specimen at which metrology is performed. In metrology, such locations may also be commonly referred to as targets, marks, and so on. The “locations” described herein are defined as any specimen location at which a measurement is intentionally performed. Therefore, the locations may vary depending on the metrology being performed. As described further herein, one significant advantage of the embodiments described herein is that they are flexible as to the spatial or locational characteristics of the first and second locations.

The computer system may be configured for inputting the first information into the encoder, which may then transform the first information as described further herein. The computer system may input the first information into the encoder in any suitable manner, and the first information may have any suitable form or format known in the art. The computer system may be configured to acquire the first information (and other information described herein like the second information) in any suitable manner. For example, the computer system may be configured to generate the first information using a system or tool such as those described herein. In such instances, the computer system may be part of the system that generates the information and may be configured to cause the system or tool to generate the information, e.g., by performing a metrology or other process on the specimen. Alternatively, the computer system may acquire the information from another method or system that generates the information. For example, the computer system may acquire metrology information from a storage medium, such as those described further herein, in which it has been stored by a metrology tool that generates the information. Other information described herein may be acquired in a similar manner, may be input to the transformer in a similar manner, and may have any suitable form or format known in the art.

A user may also provide input to the computer system that is then input to the transformer. For example, the computer system may be configured with a user interface (UI) via which a user can input information such as the locations to which the first information is upsampled. The UI may have any suitable configuration so that the user may select, upload, input, or otherwise control the information input to the transformer by the computer system.

A set of locations (e.g., “first locations”) may also be referred to herein and in the art as a template, grid, array, sample, etc. of locations. In general, the terms “template” and “grid” as used herein are defined as a set of fixed specimen locations used by or for metrology sampling. In one such example, a “template” may include 100 positions distributed equally over the specimen. In the case of first locations, at each of these 100 positions, a measurement is performed to thereby generated metrology information like overlay or CD. In another example, the first locations (and possibly the second locations) may correspond to certain marks configured specifically for metrology. In one such example, the first locations may include locations of overlay marks formed on the specimen and designed for overlay metrology. In a different such example, the first locations may include locations of patterned features of interest in the design for the specimen and formed on the specimen. The patterned features of interest may include non-device features that are formed on the specimen not for device function but for metrology or other purposes. Alternatively, the patterned features of interest may be device features formed on the specimen. The first and second locations may also be unpatterned locations on the specimen. For example, the first and second locations (sparse and dense, respectively) may be regular grids or arrays spread evenly across the specimen when the metrology being upsampled is something like height of the wafer surface measured by a metrology tool such as an interferometer. Any of such first locations may be setup in a “measurement recipe” on the metrology tool.

The first information includes information generated for the first locations by one or more tools that perform one or more processes on the specimen. The one or more tools include a metrology tool. The metrology tool may have any of the configurations described herein. The one or more tools, therefore, include at least a metrology tool, and the first information includes at least some measurement results generated for the first, relatively sparse locations on the specimen. As also described herein, however, the information that is generated by the metrology tool may include not just the measurement results, like CD measurements, overlay measurements, etc., but also any other output generated for the specimen by the metrology tool. In addition, as described further herein, the information included in the first information may include information generated by one or more other tools that performed a process on the specimen. Such tools may include one or more fabrication process tools such as lithography and etch tools that performed one or more processes on the specimen. The information generated by such process tools that may be included in the first information is described further herein.

The first information may include information generated for the specimen by more than one metrology tool and/or by more than one metrology process. For instance, different metrology processes may be performed on the same specimen after different fabrication processes are performed on the specimen. In one such instance, a first metrology process may be performed for one specimen layer, and a second metrology process may be performed for another specimen layer formed after the first specimen layer. In some cases, the specimen characteristics of an underlying layer may affect the specimen characteristics on an upper layer and/or the measurements performed on the upper layer (as when a metrology tool can “see” portions of the specimen underneath the layer, patterned features, etc. being measured). In this manner, if measurements have been performed for the underlying layer (with the same or different metrology tool or process used for the upper layer), the measurements for the underlying layer may also be input to the encoder. Any output generated by multiple metrology tools and/or processes for the first locations on a specimen may be input to the encoder in the same manner described herein. Via training of the transformer, the transformer can learn how to upsample any of the first information generated at the first, relatively sparse locations to second, relatively dense locations.

In another embodiment, the first information includes first coordinates for the first locations. The first coordinates may include any suitable coordinates including, but not limited to, specimen coordinates and field coordinates. The first coordinates may also vary depending on the metrology tool and the measurements performed on the specimen by the metrology tool. In most cases, the first coordinates will be determined by the metrology recipe, which controls how the metrology is performed, and the first coordinates will generally be output with the metrology results from which the computer system can acquire them.

One significant advantage of the embodiments described herein over currently used upsampling methods and systems is that they provide the possibility for integrating not just metrology measurements into the model (e.g., all available specimen/process information may be integrated). In one such example, the embodiments may refine the model with context (e.g., related to the metrology and/or a fabrication process performed on the specimen as described further herein). In addition, the embodiments can add more metrology sources like any measurements that are performed prior to metrology, e.g., by a fabrication process tool that during a fabrication process generates metrology or metrology-like information for a specimen.

In one embodiment, the information included in the first information and generated by the metrology tool includes one or more characteristics of the specimen measured at the first locations by the metrology tool and one or more measurement related variables generated by the metrology tool at the first locations. In this manner, the transformer can be refined with metrology-related context, meaning that for each specimen location, the embodiments can add information for the transformer to use for upsampling. The context may include “string” based information about the metrology process related to the specimen locations. In one such example, the context information may include the metrology tool “name,” ID, type, or other metrology tool characteristics. The transformer may use this information in various ways such as learning that if a measurement came from metrology tool A, the metrology information generated for the first specimen locations and input to the transformer should be interpreted differently than measurement information from metrology tool B. One reason why metrology information from different metrology tools may be treated differently is if different tools have different measurement accuracy. The one or more measurement variables may also vary depending on the metrology to be upsampled.

The measurement related variables may also or alternatively include an output parameter at the first locations or measurement locations of interest. For example, the embodiments described herein are configured to “predict” metrology information like overlay on un-measured sites (upsampling), but some tools output a lot more information than just the measurements at the measured sites depending on the metrology used. In one such example, an overlay measurement performed with optical imaging may generate information including, but not limited to, image contrast, grey level, focus level, and fit quality (output when overlay is measured by fitting certain structures via image analysis). In another example, for electron beam CD/overlay (OVL) measurements, the metrology output may include parameters like voltage, vibrations, etc. that can impact the quality of the final measurement. Such tools may also directly output something like “measurement accuracy” (which they may calculate internally from various sources of measurement errors).

In a further embodiment, the one or more tools include a fabrication process tool configured for performing a process on the specimen to thereby alter one or more characteristics of the specimen, and the information included in the first information includes information generated for the specimen by the process tool during the process. In other words, a fabrication process tool as that term is used herein is a tool that intentionally makes changes to a specimen in one or more ways like patterning a material on the specimen, etching a material, depositing a material, implanting ions, etc. These tools are different from yield-related tools like inspection tools, metrology tools, and defect review tools (to name a few) in that such tools are not designed to intentionally make changes to the specimen. Some examples of fabrication tools are described further herein. As shown more generally, in FIG. 1, fabrication process tool 157 may include one or more sensors 159, which may output various information such as that described herein. One or more components 153 including transformer 155 may acquire such output as described further herein from the process tool, the sensor(s), or a computer-readable storage medium in which the output has been stored.

In this manner, the transformer can be refined with semiconductor fabrication-related context. The context information may therefore be somewhat removed from the metrology process (meaning it is not generated by the metrology process itself). In some such examples, the information generated by the fabrication process tool during the process may include a certain setting/parameter on a tool like a lithography scanner (e.g., exposure chuck information, reticle ID information, illumination conditions, etc.) that was used in an exposure step performed before the metrology process. The information generated by the fabrication process tool may also include leveling (LVL) gradients. In the case of leveling (which is height information), the fabrication process tool-generated information may be used to calculate the local gradient at the first locations (and the second locations as described further herein). The gradient can have an impact on leveling (a relatively strong gradient in topography that can induce stress in the wafer which then can create misalignments or overlay errors). In another example, the one or more tools may include an etch tool, which may include one or more temperature sensors, and the first information may include temperature information generated by the one or more temperature sensors during an etch process performed on a specimen. In a further example, some fabrication tools like etch and deposition tools may have a whole array of sensors spread over and/or under a wafer in a spatial distribution. If any such sensors output relevant information at different locations with respect to the specimen, the transformer described herein may be configured to learn how to use that information for upsampling in the same manner described herein. Therefore, the information generated by the process tool that is included in the first information may include any relevant process information and may vary depending on the fabrication processes that are performed on the specimen prior to metrology and the process tools that performed the fabrication processes.

In the case of both metrology and fabrication process context information, the context information that is used may be less than all of the possible context information output by the tools. For example, the context information that is available for use in the embodiments described herein may be quite extensive, and the context information that is actually used may be selected to include only the metrology and/or fabrication information that might have an impact on the upsampled measurement information itself. In one such example, a fabrication tool may generate a significant amount of information during a fabrication process performed on a specimen. The specimen characteristics (as formed on the specimen) may be more or less affected by each of the different types of information. For example, specimen characteristics like CD may be more affected by leveling information, exposure dose, and focus rather than date and time at which the specimen was patterned. Therefore, if the upsampling described herein is performed for CD, the date and time of the lithography process may not be used as context information, but the other information described above may be. Similar considerations may be made when determining which metrology-related information is input to the transformer as metrology context information.

Each first location may be configured as a vector with elements containing metrology measurement results (e.g., overlay in x and y), its position in coordinates (e.g., specimen and/or field coordinates), any measurement related variables (e.g., measurement quality), and any other relevant information from a fabrication process tool (e.g., direction and magnitude of LVL gradients and others).

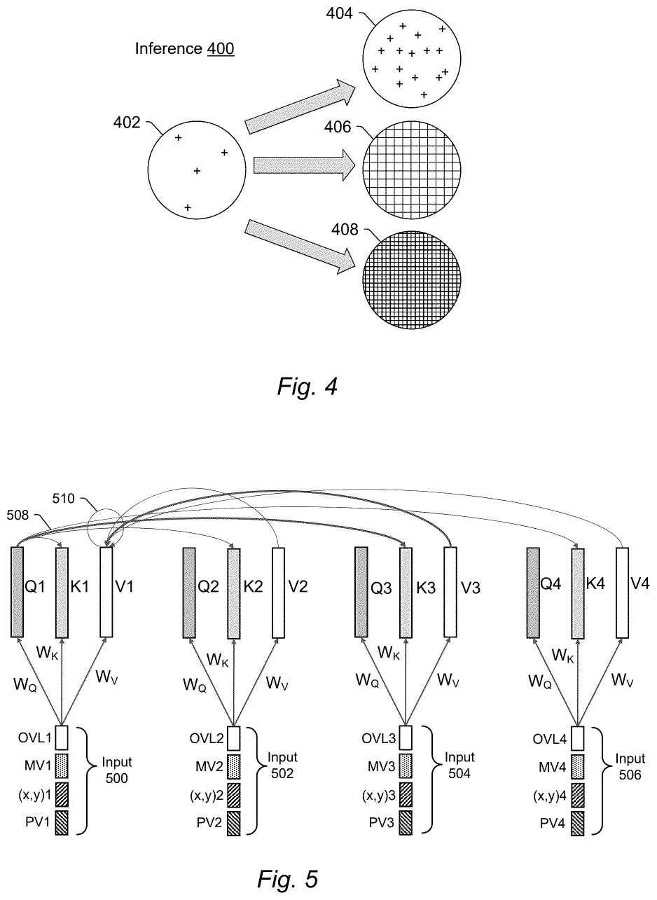

FIG. 5 illustrates conceptually how the encoder may perform self-attention for specimen location-based (mark-based) information. Using three matrices W_{V}, W_{K}, and W_{Q} (shared for all specimen locations), each specimen location vector is transformed into a value (V), key (K), and query (Q) vector. Transforming each location vector into a value, key, and query vector may be performed using a simple matrix multiplication, which takes a vector of size N and multiplies it with a vector of size (M,N) to yield a vector of size (M).

For each location (represented as a vector), the attention scores may be calculated (using the respective location's query and the keys of all locations including itself) that reflect which other locations this location most closely relates to. The attention score may be calculated as the dot product between keys and queries (for each possible pair of locations). These attention scores may then be passed through a softmax operation ensuring that they sum to 1. These scores may then be used as weights in a weighted average of all the values in the set. For example, each specimen location receives the value vectors from all locations weighted by the attention score of the respective combination. This step may be thought of as a “smart weighted average.”

FIG. 5 shows self-attention performed for 4 different locations. FIG. 5 and the following description are presented here in perhaps the most simple and general terms, not to convey an actual implementation of the transformer architecture or function, but to convey the core idea of how the embodiments can function and can be configured. As would be clear to one of ordinary skill in the art, many variations of the architectures described herein are possible, and the actual architecture that is used may depend on the use case for which it is designed and/or adapted. For example, the architectures described herein may be modified so that a mathematical function may be applied to the output of one layer before it is input to the next layer. In addition, the parameters of some elements of the architecture may be learned or vary from use case to use case. In just one such example, some of the matrices described herein may have different parameters from use case to use case and even from each other. Obviously, then the architectures that are described herein may be modified to optimize the performance of the transformer as is normally performed when designing a commercial computer-implemented method or product.

Returning to FIG. 5, then, each location has its own input (e.g., input 500 for location 1, input 502 for location 2, input 504 for location 3, and input 506 for location 4). The inputs for each location may include any of the information described herein. For example, for first locations, the inputs may include metrology information, e.g., OVL1 for location 1, OVL2 for location 2, OVL3 for location 3, and OVL 4 for location 4. The inputs may also include metrology-related variables (MV), e.g., MV1 for location 1 and so on. In addition, the inputs may include the coordinates for each location, e.g., (x, y)1 for location 1 and so on. The inputs may further include information generated by a fabrication process tool or fabrication process-related variables (PV), e.g., PV1 for location 1 and so on.

Using three matrices (W_{Q}, W_{K}, and W_{V}) shared for all locations, each location vector with elements included in its respective input is transformed into a value, key, and query vector. The matrices are learnable parameters of the transformer (there may be one set of independent matrices per head per block). In other words, the matrices, transform input 500 for location 1 into query for location 1 (Q1), key for location 1 (K1), and value for location 1 (V1). The inputs for each other location may be transformed in the same manner into their respective queries, keys, and values, e.g., query Q2 for location 2, key K2 for location 2, and value V2 for location 2, and so on.

FIG. 5 shows how the attention score may be calculated for location 1 as the dot product between keys and queries for each possible pair of locations. In particular, arrows 508 show how query Q1 for location 1 may query each key for each of the locations. The encoder may then calculate the attention score as the dot product between the keys and queries for each pair of location 1 and each other location. As shown by arrows 510, location 1 receives the value vectors from all locations weighted by the attention score of the respective combination. This step is visualized in FIG. 5 for location 1 with relatively high contribution from location 3 (as indicated by the relatively bold arrows between Q1 and K3 and V3 and V1). These steps may be performed for each of the locations.

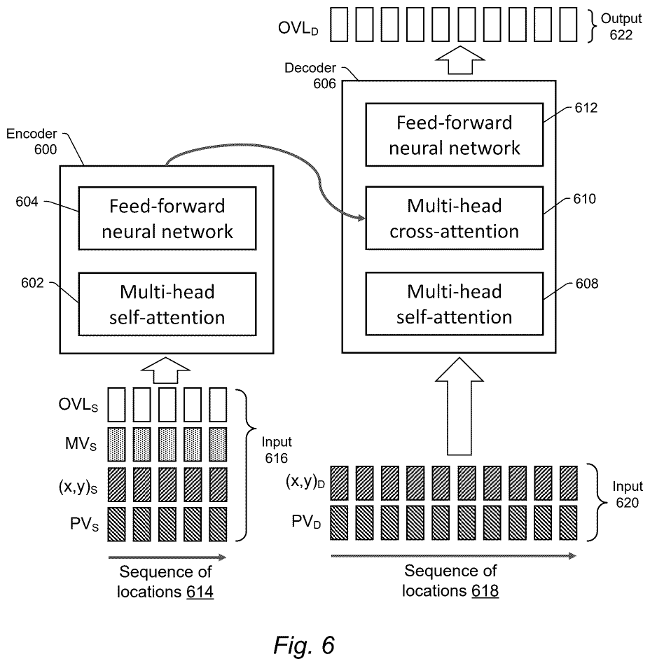

In one embodiment, the encoder includes multiple encoder blocks, and each of the multiple encoder blocks includes a multi-head self-attention layer and a feed-forward neural network (FFN) layer. One embodiment of a transformer that includes such an encoder is shown in FIG. 6. In particular, the transformer may include an encoder that may include N_{enc} number of encoder blocks 600, and N_{enc} is a hyperparameter that is selected when setting up the transformer. Each of the encoder blocks includes multi-head self-attention layer 602 and feed-forward neural network block 604. The input to the encoder blocks includes input 616 for sequence of locations 614. The sequence of locations may be any of the first locations described herein. In addition, the input for each location in the sequence may include any of the information described herein including metrology information (e.g., OVL for the sparse locations (OVL_{S}), metrology-related variables for the sparse locations (MV_{S}), coordinates of the sparse locations ((x, y)_{S}), and fabrication process-related variables for the sparse locations (PV_{S})). As described further herein, the encoder, using multiple encoder blocks that contain self-attention layers, encodes the first information for the relatively sparse locations by allowing an exchange of the relevant information between marks using self-attention.

In a normal self-or cross-attention layer, the layer determines one set of attention scores in each step (and subsequently aggregates the information from these locations as one weighted sum). In multi-head attention, the attention scores and their softmax in N smaller subspaces of the model are calculated. While before, in each step, each location could “attend” to other locations based on a single dot-product similarity of their keys and queries, it could now, theoretically, attend to many other locations based on multiple dot-product similarities of their keys and queries. As a purely hypothetical example, in one attention head of the model, the locations can check whether they part of a strong edge signature, while in another head, the locations can check whether they are an outlier with regards to their neighboring locations.

The FFN blocks included in each of the encoder blocks (and the decoder blocks as described further herein) are configured for position-wise operation (based on the input sequence). So, each token can be processed individually. In addition, the FFN blocks may have a non-linear activation function (like rectified linear unit (ReLU)) to introduce non-linearity. In the end, these blocks make it possible to encode (and decode) substantially complex correlations that may be performed in the embodiments described herein.

The transformer also includes a decoder configured for transforming second information for second locations on the specimen by self-attention thereby generating a second encoded representation of the second information. The decoder may perform self-attention for the second information in the same manner as described herein. In other words, the self-attention that is performed by the encoder and decoder may be performed in the same manner and with the same or similar architectures. The self-attention performed by the encoder and decoder is, however, performed with different parameters learned via the training described herein. One main reason why the encoder and decoder may perform self-attention with, say, the same architecture but different parameters is that the inputs to the encoder and decoder are different. Therefore, the two components may learn different self-attention parameters for encoding the different inputs.

The second locations are more dense than the first locations. The second locations may be denser than the first locations in a number of different ways. In general, the second locations are denser than the first locations in that there are a greater number of the second locations per unit area on the specimen than the first locations. For example, the second locations may include a number of locations within an area defined by multiple first locations. In this manner, the second locations may fill in the sampling between the first locations. The second locations may also or alternatively be located outside of an area across which the first locations span.

The first and second locations may each be arranged on the specimen in a regular grid, array, or template of locations although that is not necessary. For example, the first and second locations may correspond to certain patterned features of interest in a design for the specimen, which are usually though not necessarily arranged in a regular grid on the specimen. Furthermore, as described further herein, one significant advantage of the embodiments described herein is that they provide flexibility for the second locations (in addition to the first) without additional training of the transformer. Therefore, the embodiments do not have to upsample to a fixed set of second locations. The first and second locations are also referred to herein simply as the sparse locations and the dense locations, respectively.

In one embodiment, the second information includes second coordinates for the second locations, respectively. The second coordinates may include any suitable coordinates including, but not limited to, specimen coordinates and field coordinates. The second coordinates may include any other types of coordinates described herein and known in the art. In general, the first and second coordinates may be the same types of coordinates so that inference is performed within the same coordinate space. However, the computer system may be configured for translating the coordinates of any of the locations described herein from one space to another (e.g., from specimen coordinates to design coordinates, from specimen coordinates to field coordinates, etc.).

In another embodiment, the one or more tools include a fabrication process tool configured for performing a process on the specimen to thereby alter one or more characteristics of the specimen. In one such embodiment, the second information includes information generated for the specimen by the fabrication process tool during the process. In general, the first and second information may include information generated by the same fabrication process tool in the same process performed on the specimen. For example, if overlay measurements are being upsampled for a specimen, the first information may include leveling information generated by a lithography exposure tool at the first locations, and the second information may include leveling information generated by the same lithography exposure tool in the same process at the second locations. While including the same process-related variables in both the first and second information generated at the first and second locations, respectively, on a specimen may be the most common implementation, the embodiments are not limited in this manner. For example, in some cases, it may be found via training that the transformer produces better upsampled results if the second information includes more or different fabrication process-related variables than the first information. The opposite may also be true.

If the same fabrication process-related variables are included in the first and second information at the first and second locations, respectively, the encoder and decoder may learn to use these fabrication process-related variables differently. For example, some fabrication process-related variables may be essentially ignored by the encoder but weighted heavily by the decoder. In other words, the encoder and decoder will learn how to use the fabrication process-related variables for upsampling, and therefore they may apply different weights or other parameters to those variables. In this manner, the encoder and decoder may use the same fabrication process-related variables in different ways.

In another such embodiment, the second information includes only information generated for the specimen by the process tool during the process and second coordinates for the second locations. In other words, the second information will not include metrology results or measurement-related variables for the second locations because if that information was available for input there would be no need to upsample metrology results from the first locations to the second locations.

The transformer is also configured for transforming the first and second encoded representations by cross-attention into metrology information for the second locations. The cross-attention performed by the decoder enables the transformer to attend to different parts of the input sequence while generating the output. This mechanism allows the model to consider the relevant context from the encoder's output during the generation of each element in the output sequence. In other words, the cross-attention performed by the decoder basically uses both the first encoded representation of the information for the sparse locations and the second encoded representation of the information for the dense locations to generate upsampled metrology information at the dense locations. The cross-attention function therefore essentially infers the metrology information at the dense locations from the sparse location information and dense location information learned by the encoder and decoder, respectively.

In one embodiment, the decoder includes multiple decoder blocks, and each of the multiple decoder blocks includes a multi-head self-attention layer, a multi-head cross-attention block, and a FFN layer. Therefore, the decoder may include some of the same types of blocks that are in the encoder. Unlike the encoder though, the decoder includes a multi-head self-attention layer. For the same types of blocks in the encoder and decoder, those blocks may have the same or similar configurations, possibly with different hyperparameters in the encoder and decoder blocks (e.g., numbers of layers, sizes, etc.).

As shown in FIG. 6, the decoder may include N_{dec} number of decoder blocks 606, and N_{dec} is a hyperparameter that is selected when setting up the transformer. Each decoder block 606 includes a multi-head self-attention layer 608, a multi-head cross-attention layer 610, and a feed-forward neural network 612 layer. Input 620 to the decoder blocks for dense sequence of locations 618 may include coordinates of the dense locations ((x, y)_{D}) and fabrication process-related variables for the dense locations (PV_{D}). In this manner, the decoder only receives the positions and spatially-available predictors such as LVL gradients as inputs. The cross-attention blocks in the decoder then query the encoded representations of the sparse locations to transform the dense sequence of locations and fabrication process-related variables into output 622 that includes metrology information like OVL (OVL_{D}) for each of the dense locations in the input sequence.

One reason why the architectures of the encoder and decoder are different is that the encoder's only task is to transform the initial set of embedded location vectors into a “useful representation” for the decoder. The decoder has both components of the former (self-attention and FFN), but also cross-attention blocks. In these, only the query vector is derived from the decoder inputs (x, y)_{D} and corresponding PV_{D}. The keys and values are derived from the encoded representation (the outputs of the encoder). Multi-head cross-attention can be thought of as the embedded target sequence (the coordinates and fabrication process-related variables of the relatively dense sequence) querying and then receiving the values of those encoded locations that best reflect the metrology information (e.g., overlay) at their positions.

Each of the blocks shown in FIG. 6 and described herein may have any suitable configuration known in the art. In addition, each of the blocks included in the encoder and decoder may include any other suitable layers having any suitable configuration known in the art. Such layers include, but are not limited to, convolutional layers, pooling layers, softmax layers, fully connected layers, normalization layers, skip connections, and the like.

In another embodiment, the transformer is configured so that the first information is not input to the decoder. For example, as shown in FIG. 6, the first information for the first, relatively sparse locations is not input to the decoder. Instead, the decoder only receives the coordinates and the fabrication process-related variables for the second, relatively dense locations. In addition, as shown in FIG. 6, the first encoded representation that is generated by the encoder blocks is input to multi-head cross-attention block. Therefore, the decoder blocks receive the encoded representation of the first, relatively sparse locations, but not the input to the encoder blocks for the first locations. Furthermore, the output of the encoder is not output by the transformer. In other words, output 622 shown in FIG. 2 does not include any results generated by the encoder. Those results are only available to the decoder that uses them to generate the upsampled metrology results.

The differences in the inputs to the encoder and decoder are by design. For example, an important aspect of the encoder is that it might learn on a variety of variables and contexts (such as those described further herein including leveling information, quality parameters, context like tool name, and so on) and of course the metrology values (like overlay) at the coordinates of the first locations. The decoder will likely have less dimensions. For instance, the decoder would of course have no information for the metrology values (that is what is being predicted at the dense locations) and also no other metrology-related variables (like measurement quality). On the other hand, the input to the decoder may include as much information as possible in the same manner as the encoder. For example, information from an exposure that was performed before the metrology step may be available and may then be used as input to the decoder. Regardless of the differences in the inputs to the encoder and decoder, one important thing they have in common is that they are both flexible in the number of input and output locations. In other words, the sequences of locations 614 and 618 input to the encoder and decoder, respectively, are flexible in various advantageous ways described further herein, which is an important improvement over previously used upsampling methods.

One significant advantage of the embodiments described herein is that they can be used as an upsampling method for any kind of metrology. In other words, the embodiments described herein are not specific to the type of metrology that is upsampled. In particular, the embodiments are not specific to what is measured during the metrology (i.e., which specimen characteristics are measured) or how it is measured (e.g., with light, electrons, ions, etc.). In one embodiment, the metrology information includes a CD of one or more patterned features formed at the second locations. The CD may be any dimension of interest for any patterned feature of interest. Some examples of CDs that may be of interest for the embodiments described herein include, but are not limited to, line widths of trenches and spaces and diameters of contact holes.

In another embodiment, the metrology information includes overlay, of first patterned features on a first layer of the specimen relative to second patterned features on a second layer of the specimen, at each of the second locations. For example, the embodiments described herein are particularly useful for upsampling overlay and may be performed for first locations corresponding to overlay marks, e.g., patterned features on a specimen designed specifically for overlay measurements. Generally, overlay is measured and monitored to make sure that the patterned features on an upper layer of the specimen are properly aligned with patterned features on an underlying layer of the specimen. Therefore, the first layer may be the uppermost layer on a specimen, and the second layer may be an underlying layer on the specimen. The overlay may be measured, for example, as the extent of misalignment (in x and/or y) of patterned features on the different layers to each other.

In some embodiments, the one or more tools include a lithography tool configured for performing a lithography process on the specimen, the information included in the first information and the second information includes information generated for the first and second locations, respectively, on the specimen by the lithography tool during the lithography process, and the metrology information includes overlay measurements. For example, one particularly useful implementation of the embodiments described herein is upsampling overlay measurements (although the embodiments can be used for other metrology measurements described herein). Upsampling overlay measurements may also particularly benefit from integrating process-related variables in the first and second information input to the encoder and decoder, respectively, for the first and second locations, respectively.

In one such example, the first and second information may include, but are not limited to, sparse and dense leveling information at the first and second locations, respectively, that is generated by a lithography tool during a lithography process performed on the specimen. For example, overlay metrology is usually performed after an exposure step performed by a lithography tool (like a scanner). Some settings of the lithography tool can have an impact on the overlay and therefore may be beneficial to input to the encoder and decoder for upsampling. In the lithography tool, there is one step called “leveling” performed before each exposure that measures the height topography of the wafer in a substantially dense grid. The embodiments described herein can therefore extract the leveling information for the first and second locations and input it to the transformer. Other processes in the lithography tool include, for example, alignment and setting a particular dose for each point on the wafer. Results of such processes are additional examples of possible inputs to the transformer (e.g., the applied dose at the metrology locations of interest).

A significant advantage and improvement of the embodiments described herein over other currently available upsampling methods and systems is that the transformer architecture is flexible with regards to the input and output data structure. In other words, a significant advantage of the embodiments described herein is that they do not rely on a certain fixed input or output template (i.e., exactly these 100 marks in a certain order at defined locations). This flexibility is important for a number of reasons. For example, there might be multiple different samplings available via the embodiments described herein. In another example, some input measurement results for one or more specimen locations may be missing or tagged as flyers. “Flyers” as that term is used herein is defined as outliers or mis-measurements. For example, a specimen location may have been damaged during a process, and the metrology tool may not be able to generate a measurement result at that location. Some metrology processes also detect outliers (e.g., outlying metrology results) and remove them before they are available as input to the transformer. As such, there may be “gaps” in the measurement results that are input to the transformer, and the flexibility of the transformer architecture described herein can advantageously adapt to such flyers. In an additional example, multiple different output samplings (grids/templates) may be desired. Without the flexibility described herein, different models would have to be trained for each different location sample described above.

To illustrate one specific example in which the flexibility of the embodiments described herein is advantageous, for a lot of ML applications, the input is usually a fairly big table with columns defining different input parameters. An “easy” way for predicting something based on input metrology tool data would be to put metrology measurements for say 100 locations into 100 input columns. Each row in each column may be the individual measurements per specimen (repeated as needed for training). One issue that many ML applications have is when there are fewer inputs that it was trained for, e.g., only 95 inputs instead of the 100 for which it was trained. Most ML models have no way to adapt to the different size input without re-training. Obviously, that re-training is disadvantageous for a number of reasons such as the time and expense involved. In addition, as described further herein, the size of the input may vary unexpectedly (as in the case of “flyers”), and the sizes of the inputs and outputs may vary intentionally (e.g., when a metrology process that generates at least a part of the first information is intentionally changed thereby changing the first locations at which metrology information is generated and/or when the desired upsampling (and therefore the second locations) are intentionally changed).

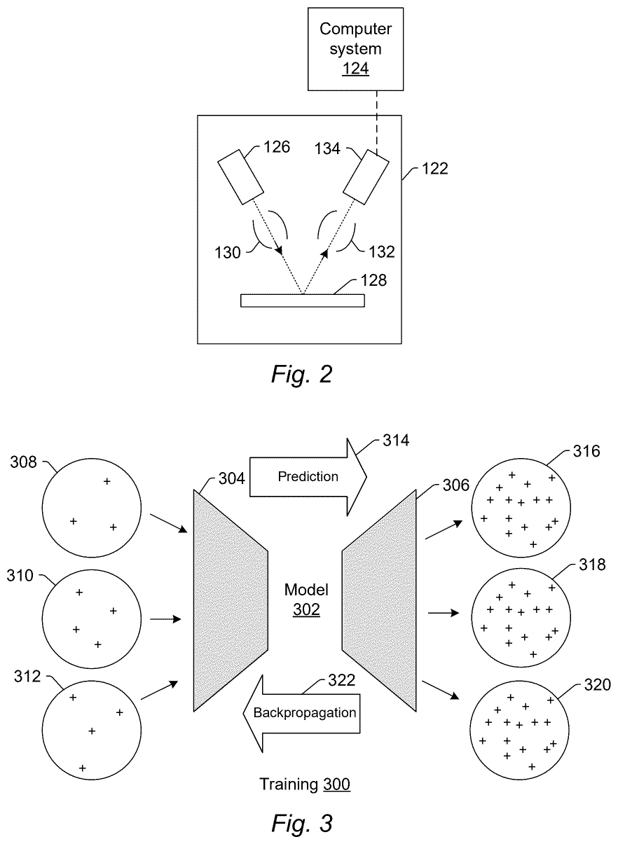

FIG. 3 illustrates schematically how the transformer may be trained by the embodiments described herein. Training 300 is performed to establish the connection between a diverse set of sparse and dense metrology data. For example, model 302 (the transformer described herein) includes encoder 304 and 306, each of which may be configured as described further herein. During the training phase, training information may be input to the transformer, which then performs predictions 314. The predictions are the upsampling described herein in which first information for first locations that are relatively sparse on a specimen and include at least metrology information for the first locations (e.g., at least measurements and first location coordinates) are upsampled to generate metrology information for second locations that are relatively dense on the specimen. For example, different instances 308, 310, and 312 of training input data that include sparse metrology information in addition to any other types of information described herein may be input to model 302 thereby generating different instances 316, 318, and 320, respectively, of upsampled metrology information at second training locations. The output of the transformer may be compared to training output information (not shown) and results of the comparisons may be used for altering one or more parameters of the transformer (e.g., via backpropagation 322) until the modeled output matches (or substantially matches) the training output. The one or more parameters of the transformer that are altered during training may include any alterable parameters of the transformer, the encoder, the decoder, etc.

As shown in FIG. 3, the first training information may include different instances 308, 310, and 312 of relatively sparse metrology information and the coordinates at which the metrology information was generated (shown schematically in FIG. 3 simply as wafer map locations), and the first and second training information used for each of the different instances may include any other types of information described herein. For example, for any one instance of training data, the training data may also include any of the measurement related variable(s) described herein for the first training locations, any of the information generated by one or more fabrication process tools described herein for first and second training locations, and second coordinates for second training locations. In addition, although the inputs and outputs of the model are shown in FIG. 3 as wafer maps, which are useful for illustrating the differences in location density between the first and the second locations, the inputs and outputs can have any suitable configuration, form, and format.

In one embodiment, the transformer is trained with training data that includes first training information for first training locations, one or more locational characteristics of the first locations are different than one or more locational characteristics of the first training locations, and the encoder is configured for transforming the first information for the first locations without re-training of the transformer. In other words, the transformer provides flexibility in the sparse location input in that the first locations used to train the encoder may have different spatial or locational characteristics than the first locations used for inference upsampling without re-training of the transformer. The locational characteristics of the first locations during training and inference may be different in a number of different ways. For example, the first locations used for training and inference may be different in number, arrangement on the specimen (e.g., regular array versus irregular, etc.), density, frequency, etc. In this manner, the sparse locations used for training and inference may be different sets of first locations that have one or more different locational characteristics. Obviously, other inputs for the first locations, like measurement results, measurement-related variables, and fabrication process-related variables, may also be different because they will vary depending on the first locations and the measurements generated for the training and runtime specimens by the various tools described herein.

“Re-training” as that term is used herein includes any training of the transformer that is performed after the transformer is initially trained and released for use. In this manner, the re-training may include re-training the transformer again from scratch, performing additional training of the transformer, performing fine-tuning of the transformer via training, etc.

In another embodiment, the encoder is configured for performing the first information transformations for additional first locations, on the specimen or a different specimen, having one or more different locational characteristics than the first locations without re-training of the transformer. For example, in the same way that the first locations used for training and inference can be different in their locational characteristics without re-training of the transformer, the first locations used for different inferences can be different in their locational characteristics without re-training of the transformer. This flexibility is important for a number of reasons. For example, the sampling used for a metrology process may be changed, e.g., based on observed behavior of fabrication process(es) performed before metrology and/or if changes were made to the fabrication process(es) that necessitate different monitoring to be performed. In addition, as described further herein, even if the metrology sampling is the same from specimen-to-specimen, metrology information may be missing for one or more of the sparse locations. The embodiments described herein can advantageously adapt to any of such changes without requiring changes to the transformer via re-training.

In some embodiments, the transformer is trained with training data that includes second training information for second training locations, one or more locational characteristics of the second locations are different than one or more locational characteristics of the second training locations, and the decoder is configured for transforming the second information and the first and second encoded representations for the second locations without re-training of the transformer. For example, the second locations used for training and inference can have different locational characteristics without re-training of the transformer in the same manner described above with respect to the first locations.

In a further embodiment, the decoder is configured for transforming the second information and the first and second encoded representations for additional second locations, on the specimen or a different specimen, having one or more different locational characteristics than the second locations without re-training of the transformer. In other words, once the transformer is trained as described herein, the transformer may be used for inference from any sparse input map to any dense output map without re-training of the transformer. FIG. 4 illustrates schematically an instance in which one relatively sparse input map is transformed and upsampled to different relatively dense output maps having different location densities without re-training of the transformer. In particular, as shown in FIG. 4, during inference 400, the first information may include relatively sparse first information 402 that includes any of the first information described herein. This information may be input to the encoder (not shown in FIG. 4) as described further herein, and any of the second information described herein may be input to the decoder (not shown in FIG. 4) of the transformer. The coordinates of the relatively dense locations to which the metrology information is being upsampled may vary depending on the desired degree of upsampling. For example, upsampled metrology information that may be generated for the same relatively sparse locations and different upsampling densities, without re-training the transformer, is shown schematically in FIG. 4 by the increasing densities of the upsampled metrology information from wafer map 404 to wafer map 406 and then wafer map 408.

In an additional embodiment, the transformer is trained with training data for a training specimen having a design different than the specimen, and the transformer is not re-trained prior to upsampling the specimen information. For example, one significant advantage of the embodiments described herein is that the transformer can be applied between products/layers. In one such example, the transformer may be trained on product A and then perform runtime inference for product B.

As described further herein, the embodiments are configured for transforming information via attention for sequences of locations. In one embodiment, the first and second locations are unordered sequences of the first and second locations, respectively. In other words, each of the templates described herein may be represented as an unordered sequence of locations (marks). For example, for the transformers described herein, the sequence of locations (with regard to their spatial position on the specimen) is not important. Therefore, the sequence of locations can be unordered, i.e., just a list of locations. The input and output of the transformers described herein is therefore different from some other inputs and outputs of ML models. For example, some ML models are configured for inference using ordered sequences such as text, and in such cases, the sequence of the text can change its meaning and how inference is performed for it. In the embodiments described herein, however, the sequences of the locations do not affect their corresponding information and how inference is performed for the locations.

In some embodiments, the decoder is configured for transforming additional second information generated for additional second locations on an additional specimen by self-attention thereby generating an additional second encoded representation of the additional second information and transforming the first and additional second encoded representations by said cross-attention into metrology information for the additional second locations, and the additional second specimen locations are more dense than the first specimen locations. In other words, a transformer that is trained as described herein may be able to predict the metrology information for dense locations on a specimen for which no sparse location metrology information is available. For example, with a transformer trained as described herein, the first information for first locations on a first specimen, and the second information for second locations on a second specimen, the transformer should be able to predict metrology information for the second locations on the second specimen.

In one such embodiment for upsampling overlay with fabrication process-related variables that include at least leveling information, the transformer may be trained on a number of specimens (as many specimens as possible/practical). In one such example, there may be 100 lots with 25 wafers and leveling (from the exposure tool) and overlay measured on all of them at 1000 locations. This information may be used for training.

The trained transformer may then be used at runtime for a different wafer and first information for 100 sparse locations on that wafer to predict overlay on the same wafer at 1000 dense locations. Such upsampling is the within-specimen upsampling described herein. In contrast, predicting metrology measurements for one wafer using actual metrology results generated for only a different wafer may be considered a type of “virtual metrology.” The architecture of the transformer described herein should be capable of such virtual metrology applications when suitably trained.

Across specimen sampling (e.g., within lot or between-lot sampling) would predict overlay only based on the second information (including but not limited to leveling) described herein for dense locations. For example, with respect to the inputs shown in FIG. 6, input 616 for sparse sequence of locations 614 input to encoder blocks 600 may be for a first wafer, and input 620 for dense sequence of locations 618 may be for the same first wafer or for one or more other wafers. In this manner, the metrology results and other information described herein for sparse locations on one wafer can be used to predict metrology results for dense locations on the same wafer and/or one or more other wafers (in the same lot, in other lots, etc.). In each of the predictions, the second information may change to the coordinates and any fabrication process-related variables available for the wafer for which predictions are being performed.

To describe one specific example with respect to within lot overlay upsampling for measured and unmeasured wafers in a lot, the encoder would receive the metrology results of the measured wafer(s) within a lot in addition to information that would let the model distinguish which location belongs to which wafer (e.g. context). The decoder would then receive the coordinates and fabrication process-related variables like exposure information and context of the unmeasured wafers within each lot. The architecture of the transformer described herein is well suited for this problem, because of its advantage of enabling upsampling across templates, as long as the information the transformer receives is sufficient to make inferences to completely unmeasured wafers.

The embodiments described herein have a number of important advantages over currently used methods and systems for upsampling metrology information in addition to those already described. For example, one important difference between the currently available upsampling and the embodiments described herein is that the upsampling described herein can integrate multiple data sources and process information. In particular, as described further herein, the encoder and decoder configurations and inputs are quite flexible. Some data sources may only be available for the encoder (the “sparse” data used for upsampling). This information may include metrology-related parameters received from the metrology tool such as, but not limited to, stability, tool status, mark quality, and measurement error. The inputs to the encoder and the decoder may also include fabrication process-related variables generated by one or more process tools. This “context” may include, but is not limited to, exposure tool settings, applied alignment corrections to the wafer, previous etch step settings (like etch temperature, ion flow rate, etc.), and any other fabrication process variable that might impact the metrology information.

Another advantage and improvement of the embodiments described herein over currently available upsampling methods and systems is the possibility to apply the embodiments to completely different metrology variables for new use cases. For example, the embodiments described herein were tested for overlay upsampling using inputs like leveling information and alignment information generated by a lithography scanner (exposure tool). However, the same architecture can be used to upsample other metrology measurements like a certain CD signature over the wafer (like line width), which may be performed using completely different inputs such as applied dose, applied focus, stage vibrations during exposure, wafer temperature, resist height, etc. generated by one or more process tools including any of those that performed a process on the wafer prior to metrology (e.g., not just a lithography tool but also possibly a deposition tool, a chemical-mechanical polishing (CMP) tool, an etch tool, etc.)

An additional advantage of the embodiments described herein is that the transformer and attention blocks allow training across templates (sets of locations). For example, the transformer may learn to abstract from different templates and can generalize the underlying signatures. A further advantage of the embodiments described herein is that they are more tailored towards location-fine upsampling and not the currently used “virtual metrology” (on wafer-fine context or model coefficients).

The upsampled map/metrology information that is generated by the embodiments described herein also provides a number of significant advantages over the upsampling results produced by currently available upsampling methods and systems. For example, the upsampled results generated by the embodiments described herein provide more accurate monitoring of wafer key performance indicators (KPIs) and signatures than most currently used upsampling. In addition, the upsampled results generated by the embodiments described herein provide higher order modeling for better automated process control (APC) tools than currently used upsampling.

The upsampled results generated by the embodiments described herein are also advantageous since even die-fine KPIs can be computed. For example, for die-fine KPIs, since the embodiments are flexible for the output “grid” locations, the dense locations for which overlay measurements are upsampled may include the center location of each die. These results may then be used to get an estimate for how good overlay is for each die even if overlay is actually measured only at sparse locations across the wafer initially.

A further advantage of the upsampled results generated by the embodiments described herein is that they can be a data source for further processing (e.g., combining dense CD and OVL data predicted by the embodiments described herein for edge placement error (EPE) metrics). For example, in another embodiment, the computer system is configured for determining additional information for the specimen based on the metrology information. In other words, the upsampled dense metrology information predicted by the embodiments described herein can be used in the same manner as metrology information that was actually measured at the dense locations. Obviously, the metrology information that can be determined from the upsampled metrology information will vary depending on what the upsampled metrology information is or includes. In general though, the upsampled metrology information may be input to any suitable method or algorithm known in the art to determine other metrology information for the specimen.

The computer system may also be configured for generating results that include at least the metrology information for the dense locations and optionally any of the other results or information described herein. The upsampled metrology information may be output by the computer system in any suitable manner. All of the embodiments described herein may be configured for storing results of one or more steps of the embodiments in a computer-readable storage medium. The results may include any of the results described herein and may be stored in any manner known in the art. The results that include the upsampled metrology information may have any suitable form or format such as a standard file type. The storage medium may include any storage medium described herein or any other suitable storage medium known in the art.

After the results have been stored, the results can be accessed in the storage medium and used by any of the method or system embodiments described herein, formatted for display to a user, used by another software module, method, or system, etc. to perform one or more functions for the specimen or another specimen of the same type. In addition, the results may include any information for the specimen determined as described herein.

That information may be used by the computer system or another system or method for performing additional functions for the specimen. For example, in one embodiment, the computer system is configured for modifying one or more parameters of a process performed on the specimen based on the metrology information. Modifying parameter(s) of the process may include, but is not limited to, altering a process such as a fabrication process or step that was or will be performed on the specimen in a feedback or feedforward manner, etc. For example, the computer system may be configured to determine one or more changes to a process that was performed on the specimen and/or a process that will be performed on the specimen based on the upsampled metrology information. The changes to the process may include any suitable changes to one or more parameters of the process. In one such example, the computer system preferably determines those changes such that any upsampled metrology values that are outside of an acceptable range of values are corrected on other specimens on which the revised process is performed, are corrected on the specimen in another process performed on the specimen, are compensated for in another process performed on the specimen, etc. The computer system may determine such changes in any suitable manner known in the art.

Those changes can then be sent to a semiconductor fabrication system (not shown) or a storage medium (not shown) accessible to both the computer system and the semiconductor fabrication system. The semiconductor fabrication system may or may not be part of the system embodiments described herein. For example, the metrology tool and/or the computer system described herein may be coupled to the semiconductor fabrication system, e.g., via one or more common elements such as a housing, a power supply, a specimen handling device or mechanism, etc. The semiconductor fabrication system may include any semiconductor fabrication system known in the art such as a lithography tool, an etch tool, a CMP tool, a deposition tool, and the like.

Each of the embodiments of each of the systems described above may be combined together into one single embodiment.

Another embodiment relates to a computer-implemented method for upsampling specimen information. The method includes transforming first information for first locations on a specimen by self-attention thereby generating a first encoded representation of the first information. The first information includes information generated for the first locations by one or more tools that perform one or more processes on the specimen. The one or more tools include a metrology tool. Transforming the first information is performed by an encoder included in a transformer. The transformer is included in one or more components executed by a computer system. The method also includes transforming second information for second locations on the specimen by self-attention thereby generating a second encoded representation of the second information. In addition, the method includes transforming the first and second encoded representations by cross-attention into metrology information for the second locations. The second locations are more dense than the first locations. Transforming the second information and transforming the first and second encoded representations are performed by a decoder included in the transformer.

Each of the steps of the method may be performed as described further herein. The method may also include any other step(s) that can be performed by the computer system, transformer, metrology tool, one or more other tools, etc. described herein. In addition, the method described above may be performed by any of the system embodiments described herein.

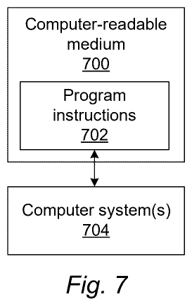

An additional embodiment relates to a non-transitory computer-readable medium storing program instructions executable on a computer system for performing a computer-implemented method for upsampling specimen information. One such embodiment is shown in FIG. 7. In particular, as shown in FIG. 7, non-transitory computer-readable medium 700 includes program instructions 702 executable on computer system 704. The computer-implemented method may include any step(s) of any method(s) described herein.

Program instructions 702 implementing methods such as those described herein may be stored on computer-readable medium 700. The computer-readable medium may be a storage medium such as a magnetic or optical disk, a magnetic tape, or any other suitable non-transitory computer-readable medium known in the art.

The program instructions may be implemented in any of various ways, including procedure-based techniques, component-based techniques, and/or object-oriented techniques, among others. For example, the program instructions may be implemented using ActiveX controls, C++objects, JavaBeans, Microsoft Foundation Classes (“MFC”), SSE (Streaming SIMD Extension), Python, Tensorflow, or other technologies or methodologies, as desired.

Computer system 704 may be configured according to any of the embodiments described herein.

Further modifications and alternative embodiments of various aspects of the invention will be apparent to those skilled in the art in view of this description. For example, methods and systems for upsampling specimen information are provided. Accordingly, this description is to be construed as illustrative only and is for the purpose of teaching those skilled in the art the general manner of carrying out the invention. It is to be understood that the forms of the invention shown and described herein are to be taken as the presently preferred embodiments. Elements and materials may be substituted for those illustrated and described herein, parts and processes may be reversed, and certain attributes of the invention may be utilized independently, all as would be apparent to one skilled in the art after having the benefit of this description of the invention. Changes may be made in the elements described herein without departing from the spirit and scope of the invention as described in the following claims.

1. A system configured for upsampling specimen information, comprising:
a computer system; and
one or more components executed by the computer system, wherein the one or more components comprise a transformer configured for upsampling specimen information, and wherein the transformer comprises:
an encoder configured for transforming first information for first locations on a specimen by self-attention thereby generating a first encoded representation of the first information, wherein the first information comprises information generated for the first locations by one or more tools that perform one or more processes on the specimen, and wherein the one or more tools comprise a metrology tool; and
a decoder configured for transforming second information for second locations on the specimen by self-attention thereby generating a second encoded representation of the second information and transforming the first and second encoded representations by cross-attention into metrology information for the second locations, wherein the second locations are more dense than the first locations.

2. The system of claim 1, wherein the transformer is trained with training data comprising first training information for first training locations, wherein one or more locational characteristics of the first locations are different than one or more locational characteristics of the first training locations, and wherein the encoder is further configured for transforming the first information for the first locations without re-training of the transformer.

3. The system of claim 1, wherein the encoder is further configured for performing said transforming the first information for additional first locations, on the specimen or a different specimen, having one or more different locational characteristics than the first locations without re-training of the transformer.

4. The system of claim 1, wherein the transformer is trained with training data comprising second training information for second training locations, wherein one or more locational characteristics of the second locations are different than one or more locational characteristics of the second training locations, and wherein the decoder is further configured for transforming the second information and the first and second encoded representations for the second locations without re-training of the transformer.

5. The system of claim 1, wherein the decoder is further configured for performing said transforming the second information and the first and second encoded representations for additional second locations, on the specimen or a different specimen, having one or more different locational characteristics than the second locations without re-training of the transformer.

6. The system of claim 1, wherein the transformer is trained with training data for a training specimen having a design different than the specimen, and wherein the transformer is not re-trained prior to upsampling the specimen information.

7. The system of claim 1, wherein the first and second locations are unordered sequences of the first and second locations, respectively.

8. The system of claim 1, wherein the information included in the first information and generated by the metrology tool comprises one or more characteristics of the specimen measured at the first locations by the metrology tool and one or more measurement related variables generated by the metrology tool at the first locations.

9. The system of claim 1, wherein the first and second information comprise first and second coordinates for the first and second locations, respectively.

10. The system of claim 1, wherein the one or more tools further comprise a fabrication process tool configured for performing a process on the specimen to thereby alter one or more characteristics of the specimen, and wherein the information included in the first information comprises information generated for the specimen by the process tool during the process.

11. The system of claim 1, wherein the one or more tools further comprise a fabrication process tool configured for performing a process on the specimen to thereby alter one or more characteristics of the specimen, and wherein the second information comprises information generated for the specimen by the process tool during the process.

12. The system of claim 1, wherein the one or more tools further comprise a fabrication process tool configured for performing a process on the specimen to thereby alter one or more characteristics of the specimen, and wherein the second information comprises only information generated for the specimen by the process tool during the process and second coordinates for the second locations.

13. The system of claim 1, wherein the one or more tools further comprise a lithography tool configured for performing a lithography process on the specimen, wherein the information included in the first information and the second information comprises information generated for the first and second locations, respectively, on the specimen by the lithography tool during the lithography process, and wherein the metrology information comprises overlay measurements.

14. The system of claim 1, wherein the encoder comprises multiple encoder blocks, and wherein each of the multiple encoder blocks comprises a multi-head self-attention layer and a feed-forward neural network layer.

15. The system of claim 1, wherein the decoder comprises multiple decoder blocks, and wherein each of the multiple decoder blocks comprises a multi-head self-attention layer, a multi-head cross-attention layer, and a feed-forward neural network layer.

16. The system of claim 1, wherein the transformer is further configured so that the first information is not input to the decoder.

17. The system of claim 1, wherein the computer system is further configured for determining additional information for the specimen based on the metrology information.

18. The system of claim 1, wherein the computer system is further configured for modifying one or more parameters of a process performed on the specimen based on the metrology information.

19. The system of claim 1, wherein the metrology information comprises overlay, of first patterned features on a first layer of the specimen relative to second patterned features on a second layer of the specimen, at each of the second locations.

20. The system of claim 1, wherein the metrology information comprises a critical dimension of one or more patterned features formed at the second locations.

21. The system of claim 1, wherein the system further comprises the metrology tool, and wherein the metrology tool is configured for generating at least a portion of the first information by measuring the first locations with one or more of light and electrons.

22. The system of claim 1, wherein the decoder is further configured for transforming additional second information generated for additional second locations on an additional specimen by said self-attention thereby generating an additional second encoded representation of the additional second information and transforming the first and additional second encoded representations by said cross-attention into metrology information for the additional second locations, and wherein the additional second specimen locations are more dense than the first specimen locations.

23. A non-transitory computer-readable medium, storing program instructions executable on a computer system for performing a computer-implemented method for upsampling specimen information, wherein the computer-implemented method comprises:
transforming first information for first locations on a specimen by self-attention thereby generating a first encoded representation of the first information, wherein the first information comprises information generated for the first locations by one or more tools that perform one or more processes on the specimen, wherein the one or more tools comprise a metrology tool, wherein transforming the first information is performed by an encoder included in a transformer, and wherein the transformer is included in one or more components executed by the computer system;
transforming second information for second locations on the specimen by self-attention thereby generating a second encoded representation of the second information; and
transforming the first and second encoded representations by cross-attention into metrology information for the second locations, wherein the second locations are more dense than the first locations, and wherein transforming the second information and transforming the first and second encoded representations are performed by a decoder included in the transformer.

24. A computer-implemented method for upsampling specimen information, comprising:
transforming first information for first locations on a specimen by self-attention thereby generating a first encoded representation of the first information, wherein the first information comprises information generated for the first locations by one or more tools that perform one or more processes on the specimen, wherein the one or more tools comprise a metrology tool, wherein transforming the first information is performed by an encoder included in a transformer, and wherein the transformer is included in one or more components executed by a computer system;
transforming second information for second locations on the specimen by self-attention thereby generating a second encoded representation of the second information; and
transforming the first and second encoded representations by cross-attention into metrology information for the second locations, wherein the second locations are more dense than the first locations, and wherein transforming the second information and transforming the first and second encoded representations are performed by a decoder included in the transformer.
